(19) United States
(12) Patent Application Publication
(10) Pub. No.: US 2025/0386584 A1
(43) Pub. Date: Dec. 18, 2025

(54) SEMICONDUCTOR DEVICE

(71) Applicant: Samsung Electronics Co., Ltd., Suwon-si (KR)

(72) Inventors: Daehyun MOON, Suwon-si (KR); Gyul GO, Suwon-si (KR); Dongsik KONG, Suwon-si (KR); Junsoo KIM, Suwon-si (KR); Jeonghoon OH, Suwon-si (KR); Sungho JANG, Suwon-si (KR); Hyunseung CHOI, Suwon-si (KR)

(73) Assignee: Samsung Electronics Co., Ltd., Suwon-si (KR)

(21) Appl. No.: 19/055,000

(22) Filed: Feb. 17, 2025

(30) Foreign Application Priority Data
Jun. 14, 2024 (KR) 10-2024-0077366

(51) Int. Cl. H10D 64/68; H10B 12/00; H10D 64/66

(52) U.S. Cl. CPC H10D 64/691; H10B 12/315; H10B 12/482; H10D 64/667

(57) ABSTRACT

A semiconductor device that includes an active pattern on a substrate, the active pattern defining a recess extending through an upper portion of the active pattern; a gate structure; and a source/drain region at an upper portion of the active pattern adjacent to the gate structure. The gate structure includes a first gate insulation pattern on an inner wall of the recess; a second gate insulation pattern having a first portion at a lower inner wall of the first gate insulation pattern, the first portion containing a metal oxide, and a second portion at an upper inner wall of the first gate insulation pattern, the second portion contacting the first portion and containing the metal oxide doped with at least one of n-type impurities, p-type impurities or germanium; and a conductive structure on the second insulation pattern.

### CROSS-REFERENCE TO RELATED APPLICATION

This application claims priority under 35 U.S.C. § 119 to Korean Patent Application No. 10-2024-0077366 filed on Jun. 14, 2024 in the Korean Intellectual Property Office, the disclosure of which is hereby incorporated by reference in its entirety.

### BACKGROUND

Some example embodiments of the present disclosure relate to semiconductor devices. For example, some example embodiments relate to DRAM memory devices including a buried gate structure.

A DRAM device may include a gate structure embedded in a substrate, and a drain region at an upper portion of the substrate adjacent to the gate structure. The gate structure may include a gate electrode containing a metal or a conductive metal nitride. Difference in work function between the gate electrode and the drain region may lead to an increase of the electric field where the gate electrode and the drain region overlap causing gate induced drain leakage (GIDL). Accordingly, the reliability of the DRAM device may decrease.

### SUMMARY

Some example embodiments of the present disclosure provide a semiconductor having improved characteristics.

Some example embodiments provide a semiconductor device. The semiconductor device may include an active pattern on a substrate, the active pattern defining a recess extending through an upper portion of the active pattern; a gate structure; and a source/drain region at an upper portion of the active pattern adjacent to the gate structure. The gate structure may include a first gate insulation pattern on an inner wall of the recess; a second gate insulation pattern having a first portion at a lower inner wall of the first gate insulation pattern, the first portion containing a metal oxide, and a second portion at an upper inner wall of the first gate insulation pattern, the second portion contacting the first portion, and the second portion containing the metal oxide doped with at least one of n-type impurities, p-type impurities or germanium; and a conductive structure on the second gate insulation pattern.

Some example embodiments further provide a semiconductor device. The semiconductor device may include an active pattern on the substrate; a gate structure; and a source/drain region at an upper portion of the active pattern adjacent to the gate structure. The gate structure may include a conductive structure extending through an upper portion of the active pattern, the conductive structure having a first conductive pattern, an interface pattern and a second conductive pattern sequentially stacked, wherein the interface pattern contains silicon; and a first gate insulation pattern having a first portion covering a lower outer wall of the conductive structure, the first portion containing a metal oxide, and a second portion covering an upper outer wall of the conductive structure, the second portion containing the metal oxide doped with impurities.

Some example embodiments still further provide a semiconductor device. The semiconductor device may include an active pattern on a substrate, the active pattern defining a recess through an upper portion of the active pattern; an isolation pattern covering a sidewall of the active pattern; a gate structure extending in a first direction parallel to an upper surface of the substrate through the upper portion of the active pattern and an upper portion of the isolation pattern; a source/drain region at the upper portion of the active pattern adjacent to the gate structure; a bit line structure contacting a central portion of an upper surface of the active pattern, the bit line structure extending in a second direction parallel to the upper surface of the substrate and perpendicular to the first direction; a contact plug structure contacting each opposite end portions of the upper surface of the active pattern; and a capacitor on the contact plug structure. The gate structure may include a first gate insulation pattern on an inner wall of the recess; a second gate insulation pattern having a first portion at a lower inner wall of the first gate insulation pattern, the first portion containing a metal oxide, and a second portion at an upper inner wall of the first gate insulation pattern, the second portion contacting the first portion and containing the metal oxide doped with impurities; and a conductive structure on the second gate insulation pattern, the conductive structure having a first conductive pattern and a second conductive pattern sequentially stacked on the second gate insulation pattern.

In a semiconductor device according to some example embodiments, a gate structure may include a conductive pattern containing a metal or a metal nitride, and a gate insulation pattern covering an outer wall of the conductive pattern and containing a metal oxide, wherein an upper portion of the gate insulation pattern overlapping a source/drain region may further contain impurities. Accordingly, an upper portion of the gate insulation pattern may suppress an increase in electric field and reduce (and/or minimize) GIDL by lowering the flat band voltage, and electrical characteristics of the semiconductor device including the gate structure may be improved.

### BRIEF DESCRIPTION OF THE DRAWINGS

FIG. 1 is a cross-sectional view illustrating a first gate structure in accordance with some example embodiments.

FIGS. 2, 3, 4 and 5 are cross-sectional views illustrating a method of manufacturing a first gate structure in accordance with some example embodiments.

FIG. 6 is a cross-sectional view illustrating a gate structure in accordance with some example embodiments.

FIGS. 7 and 8 are cross-sectional views illustrating a method of manufacturing a gate structure in accordance with some example embodiments.

FIG. 9 is a cross-sectional view illustrating a gate structure in accordance with some example embodiments.

FIG. 10 is a cross-sectional view illustrating a gate structure in accordance with some example embodiments.

FIGS. 11, 12 and 13 are cross-sectional views illustrating a method of manufacturing a gate structure shown in FIG. 10 in accordance with some example embodiments.

FIGS. 14, 15 and 16 are a plan view and cross-sectional views illustrating a semiconductor device in accordance with some example embodiments.

FIGS. 17, 18, 19, 20, 21, 22, 23, 24, 25, 26, 27, 28, 29, 30, 31, 32, 33, 34 and 35 are plan views and cross-sectional views illustrating a method of manufacturing a semiconductor device according to some example embodiments.

### DETAILED DESCRIPTION

The above and other aspects and features of the semiconductor devices and the methods of manufacturing the same in accordance with some example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a first substrate or a second substrate, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. A direction substantially perpendicular to the upper surface of the first and second substrates and may be referred to as a vertical direction.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

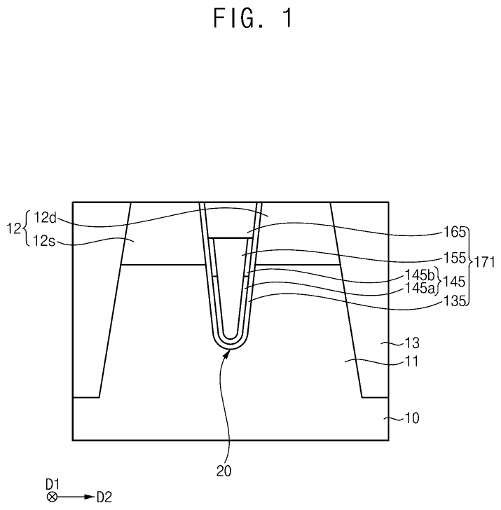

FIG. 1 is a cross-sectional view illustrating a first gate structure in accordance with some example embodiments.

Referring to FIG. 1, the first gate structure 171 may be formed in a second recess 20 extending through an upper portion of the first active pattern 11, and may include a first gate insulation pattern 135, the second gate insulation pattern 145, a first conductive pattern 155 and a gate mask 165.

The first substrate 10 may include silicon, germanium, silicon-germanium, or a III-V group compound semiconductor, such as GaP, GaAs, or GaSb. In some example embodiments, the first substrate 10 may be a silicon-on-insulator (SOI) substrate or a germanium-on-insulator (GOI) substrate.

The first active pattern 11 may be formed on the first substrate 10, and a sidewall of the first active pattern 11 may be covered by the first isolation pattern 13 on the first substrate 10. The first active pattern 11 may include the same or substantially the same material as the first substrate 10, and the first isolation pattern 13 may include an oxide, e.g., silicon oxide.

The source/drain region 12 may be formed at an upper portion of the first active pattern 11 adjacent to the first gate structure 171 in the second direction D2. The source/drain region 12 may include the material included in the first active pattern 11 and n-type impurities or p-type impurities.

The source/drain region 12 may include a source region 12s at a first side in the second direction D2 of the first gate structure 171 and a drain region 12d at a second side in the second direction D2 of the first gate structure 171 that is opposite to the first side. In the drawings, a lower surface of the source region 12s and a lower surface of the drain region 12d may be disposed at a same or substantially the same height. However, the inventive concepts are not limited thereto. That is, for example, the lower surface of the source region 12s may be lower than the lower surface of the drain region 12d.

The first gate insulation pattern 135 may be formed on a bottom and a sidewall of the second recess 20. The first gate insulation pattern 135 may include, for example, silicon oxide (SiO₂).

The second gate insulation pattern 145 may be formed, for example, conformally on the first gate insulation pattern 135. The second gate insulation pattern 145 may include a metal oxide having a high dielectric constant, for example, lanthanum oxide (La₂O₃), hafnium oxide (HfO₂), tantalum oxide (Ta₂O₅), zirconium oxide (ZrO₂), etc.

In some example embodiments, the second gate insulation pattern 145 may include a first portion 145a containing the metal oxide and a second portion 145b containing the metal oxide doped with impurities. The first and second portions of the second gate insulation pattern 145 may contact each other. The impurities may include n-type impurities, for example, phosphorus (P), arsenic (As), p-type impurities, for example, boron (B), halogen elements, for example, fluorine (F), and germanium (Ge), etc.

In some example embodiments, the second portion 145b of the second gate insulation pattern 145 may at least partially overlap the source/drain region 12 in the horizontal direction. In some example embodiments, a lower surface of the second portion 145b of the second gate insulation pattern 145 may be lower than a lower surface of the source/drain region 12.

The first conductive pattern 155 may be formed on the second gate insulation pattern 145 and fill a lower portion of the second recess 20. The first conductive pattern 155 may include a metal, e.g., tungsten (W), a metal nitride, e.g., titanium nitride (TiN), etc. In some example embodiments, when a width of the second recess 20 is relatively small, the first conductive pattern 155 may include only titanium nitride, which has a superior gap-fill characteristic compared to tungsten.

The gate mask 165 may be disposed on the second gate insulation pattern 145 and the first conductive pattern 155 to fill an upper portion of the second recess 20. In some example embodiments, a sidewall of the gate mask 165 may be covered by the first gate insulation pattern 135. The gate mask 165 may include an insulating nitride, e.g., silicon nitride.

In the first gate structure 171, an electric field of a region where the first conductive pattern 155 and the drain region 12d overlap in the horizontal direction may be suppressed by the upper portion of the second gate insulation pattern 145 further containing the impurities, and thus, flat band voltage may be lowered. Accordingly, gate induced current leakage (GIDL) due to a difference in work functions between the first conductive pattern 155 and the source/drain region 12 may be alleviated.

Compared to an example where GIDL is limited and/or prevented by additionally forming a silicon layer with a small work function difference with the drain region 12d on the first conductive pattern 155, relatively higher volume of the first conductive pattern 155 may be additionally secured in accordance with some example embodiments as described with respect to FIG. 1. Accordingly, the first gate structure 171 may have a relatively low resistance. That is, the first gate structure 171 may limit and/or prevent GIDL while maintaining low resistance, and thus, electrical characteristics and/or performance of the first gate structure 171 including the second gate insulation pattern 145 may be improved.

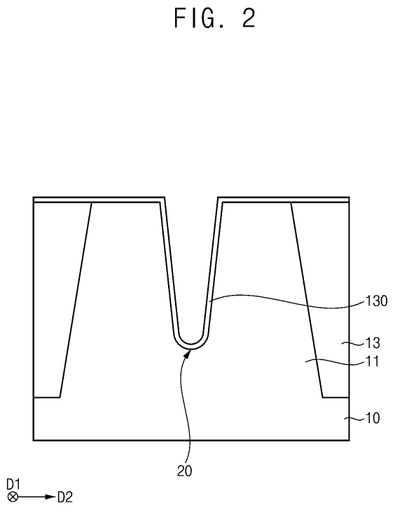

FIGS. 2 to 5 are cross-sectional views illustrating a method of manufacturing a first gate structure in accordance with some example embodiments.

Referring to FIG. 2, an upper portion of the first substrate 10 may be removed to form a first recess, and a first isolation pattern 13 may be formed to fill the first recess.

As the first recess is formed on the first substrate 10, the first active pattern 11 may be defined. The first isolation pattern 13 may be formed to cover a sidewall of the first active pattern 11.

The first active pattern 11 on the first substrate 10 may be partially etched to form a second recess 20 extending in the first direction D1, and a first gate insulation layer 130 may be, for example, conformally formed on an inner wall of the second recess 20, an upper surface of the first active pattern 11 and an upper surface of the first isolation pattern 13. For example, the first active pattern 11 of the first substrate 10 may define the second recess 20 therein, and the first gate insulation layer 130 may be conformally formed on an inner wall of the second recess 20. The first gate insulation layer 130 may include, for example, silicon oxide (SiO₂).

In some example embodiments, the first gate insulation layer 130 may be formed by a chemical vapor deposition (CVD), an atomic layer deposition (ALD), a physical vapor deposition (PVD) process, etc.

Alternatively, the first gate insulation layer 130 may be formed by performing a thermal oxidation process on the first active pattern 11. In some example embodiments, the first gate insulation layer 130 may be formed on the inner wall of the second recess 20 and the upper surface of the first active pattern 11, but may not be formed on the upper surface of the first isolation pattern 13.

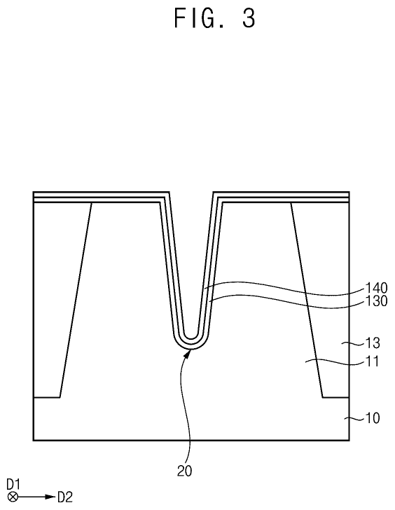

Referring to FIG. 3, the second gate insulation layer 140 may be formed, for example, conformally, on the first gate insulation layer 130.

The second gate insulation layer 140 may include a metal oxide having a high dielectric constant, e.g., lanthanum oxide (La₂O₃), hafnium oxide (HfO₂), tantalum oxide (Ta₂O₅), zirconium oxide (ZrO₂), etc.

In some example embodiments, the second gate insulation layer 140 may be formed by a chemical vapor deposition (CVD), an atomic layer deposition (ALD), a physical vapor deposition (PVD) process, etc.

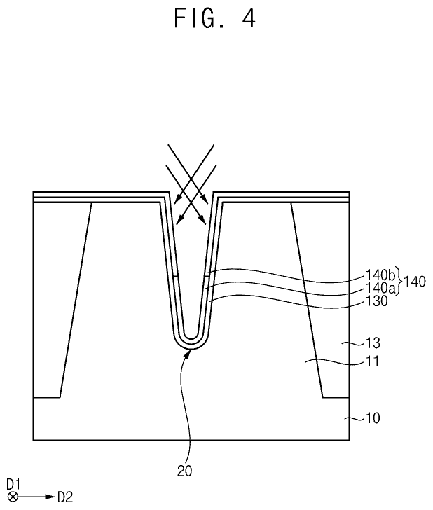

Referring to FIG. 4, a tilted ion implantation (TII) process may be performed on the second gate insulation layer 140 to implant impurities at an upper portion of the second gate insulation layer 140.

The impurities may include, for example, n-type impurities, e.g., phosphorus (P), arsenic (As), p-type impurities, e.g., boron (B), halogen elements, e.g., fluorine (F), and germanium (Ge), etc.

Hereinafter, for convenience of explanation, the upper portion of the second gate insulation layer 140 containing the impurities may be referred to as a second portion 140b, and a remaining portion of the second gate insulation layer 140 excluding the second portion 140b may be referred to as a first portion 140a.

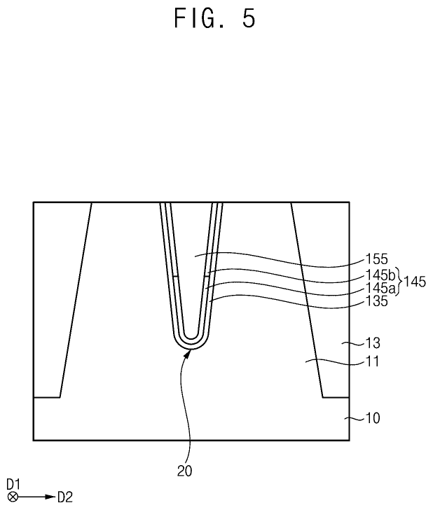

Referring to FIG. 5, a first conductive layer may be formed on the second gate insulation layer 140 to a height sufficient to fill the second recess 20, and an upper portion of the first conductive layer, an upper portion of the second gate insulation layer 140 and an upper portion of the first gate insulation layer 130 may be planarized until the upper surfaces of the first active pattern 11 and the first isolation pattern 13 are exposed to form a first gate insulation pattern 135, a second gate insulation pattern 145 and a first conductive pattern 155 sequentially stacked within the second recess 20.

The planarization process may include, for example, a chemical mechanical polishing (CMP) process and/or an etch-back process.

The second gate insulation pattern 145 may be formed to include a first portion 145a and a second portion 145b, corresponding to the first portion 140a and the second portion 140b of the second gate insulation layer 140, respectively.

Referring to FIG. 1 again, an upper portion of the first conductive pattern 155 and an upper portion of the second portion 145b of the second gate insulation pattern 145 may removed by, for example, an etch-back process to from a third recess.

A gate mask layer may be formed on the first conductive pattern 155, the second portion 145b of the second gate insulation pattern 145, the first gate insulation pattern 135, the first active pattern 11 and the first isolation pattern 13 to a height sufficient to fill the third recess, and an upper portion of the gate mask layer may be planarized until the upper surfaces of the first active pattern 11 and the first isolation pattern 13 are exposed to form a gate mask 165. The planarization process may include, for example, a chemical mechanical polishing (CMP) process and/or an etch-back process.

The first and second gate insulation patterns 135 and 145, the first conductive pattern 155 and the gate mask 165 within the second recess 20 may together form a first gate structure 171.

An ion implantation process may be performed on an upper portion of the first active pattern 11 adjacent to the first gate structure 171 in the second direction D2 to form a source/drain region 12.

The source/drain region 12 may be formed to at least partially overlap the second portion 145b of the second gate insulation pattern 145 in the horizontal direction. In some example embodiments, a lower surface of the second portion 145b of the second gate insulation pattern 145 may be formed to be lower than a lower surface of the source/drain region 12.

As described above, the inclined ion implantation (TII) process may be performed on the second gate insulation layer 140 to form the second portion 145b of the second gate insulation pattern 145 that at least partially overlaps the source/drain region 12 in the horizontal direction. Accordingly, increase of electric field in the region where the first conductive pattern 155 and the drain region 12d overlap each other may be suppressed, and GIDL caused by the increase of electric field may be alleviated.

The second gate insulation pattern 145 included in the first gate structure 171 may not directly contact the first active pattern 11, and the first gate insulation pattern 135 may be formed between the second gate insulation pattern 145 and the first active pattern 11. Accordingly, deterioration of interface characteristics between the first gate structure 171 and the first active pattern 11 due to the second gate insulation pattern 145 may be limited and/or prevented. The TII process may not be directly performed on the first gate insulation layer 130, and thus, leakage current increase due to damage of the first gate insulation pattern 135 during the TII process may be limited and/or prevented.

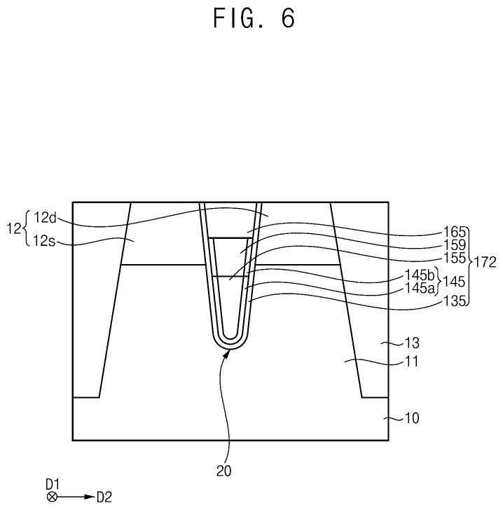

FIG. 6 is a cross-sectional view illustrating a gate structure in accordance with some example embodiments. The gate structure oof FIG. 6 may be substantially the same as or similar to the first gate structure of FIG. 1, and thus repeated explanations are omitted hereinafter.

Referring to FIG. 6, the second gate structure 172 may further include a second conductive pattern 159.

The second conductive pattern 159 may be formed on the first conductive pattern 155, and a sidewall of the second conductive pattern 159 may be covered by the second gate insulation pattern 145. The second conductive pattern 159 may include a metal, e.g., tungsten (W), a metal nitride, e.g., titanium nitride (TiN).

In some example embodiments, the width of the second recess 20 in the horizontal direction may become smaller in the vertical direction away from the upper surface of the first active pattern 11. Accordingly, a lower portion of the second recess 20, which has a relatively small width in the horizontal direction, may be formed to include a metal nitride (for example, titanium nitride) with a relatively excellent gap-fill characteristic, and an upper portion of the second recess 20, which has a relatively large width in the horizontal direction, may be formed to include a metal (for example, tungsten) with a relatively low gap-fill characteristic but a relatively low resistance.

In some example embodiments, the upper portion of the first conductive pattern 155 may further include the impurities doped in the second portion 145b of the second gate insulation pattern 145. In some example embodiments, the second conductive pattern 159 may have the same or substantially the same crystal orientation as the first conductive pattern 155.

The gate mask 165 may be formed on the second conductive pattern 159 and the second gate insulation pattern 145.

In the drawings, an upper surface of the first conductive pattern 155 and a lower surface of the second portion 145b of the second gate insulation pattern 145 may be disposed at the same or substantially the same height. However, the inventive concepts not limited thereto. That is, for example, the lower surface of the second portion 145b of the second gate insulation pattern 145 may be lower than the upper surface of the first conductive pattern 155.

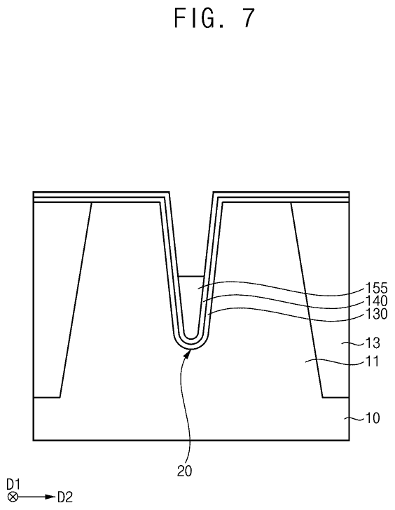

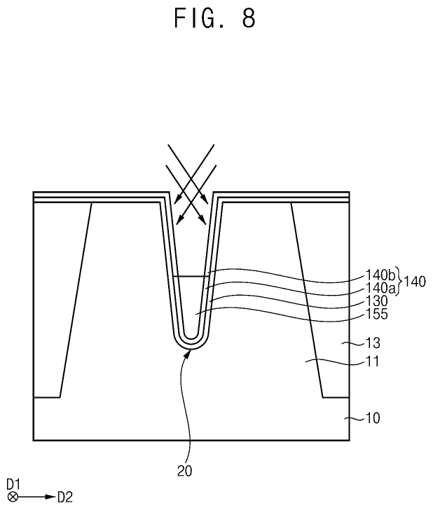

FIGS. 7 and 8 are cross-sectional views illustrating a method of manufacturing a gate structure in accordance with some example embodiments. The method of manufacturing the gate structure shown in FIG. 6 may be substantially the same as or similar to the method of manufacturing the gate structure of FIGS. 1 to 5, and thus repeated explanations are omitted hereinafter.

Referring to FIG. 7, after performing processes substantially the same or similar to the processes illustrated with reference to FIGS. 2 and 3, the first conductive pattern 155 may be formed on the second gate insulation layer 140 to fill a lower portion of the second recess 20.

In some example embodiments, the first conductive pattern 155 may be formed by forming the first conductive layer on the second gate insulation layer 140 to fill the second recess 20, and performing an etch-back process on an upper portion of the first conductive layer. In some example embodiments, the first conductive pattern 155 may include titanium nitride, which has a superior gap-fill characteristic to fill the lower portion of the second recess 20 which may have relatively smaller width in the horizontal direction D2.

Referring to FIG. 8, processes substantially the same as or similar to the processes illustrated with reference to FIG. 4 may be performed. However, during the TII process, the impurities may be partially injected into an upper portion of the first conductive pattern 155. Accordingly, the upper portion of the first conductive pattern 155 may be formed to further include the impurities.

Referring to FIG. 6 again, after forming the second conductive layer on the first conductive pattern 155 to a height sufficient to fill the second recess 20, a planarization process may be performed until the upper surfaces of the first active pattern 11 and the first isolation pattern 13 are exposed to form a second conductive pattern 159. The planarization process may include, for example, a chemical mechanical polishing (CMP) process and/or an etch-back process.

In some example embodiments, the second conductive pattern 159 may be formed by using the first conductive pattern 155 as a seed, and accordingly, crystal orientation of the second conductive pattern 159 and crystal orientation of the first conductive pattern 155 may be the same or substantially the same to each other.

Thereafter, manufacturing of the second gate structure 172 may be completed by performing processes substantially the same as or similar to the processes illustrated with reference to FIG. 1.

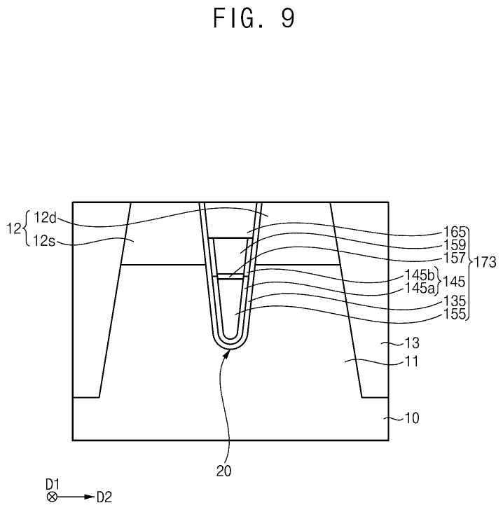

FIG. 9 is a cross-sectional view illustrating a gate structure in accordance with some example embodiments. The gate structure of FIG. 9 may be substantially the same as or similar to the second gate structure of FIG. 6, and thus repeated explanations are omitted hereinafter.

Referring to FIG. 9, the third gate structure 173 may further include an interface pattern 157 interposed between the first and second conductive patterns 155 and 159.

The interface pattern 157 may include, for example, silicon (Si). The interface pattern 157 may serve to physically separate the first conductive pattern 155 and the second conductive pattern 159 from each other.

In some example embodiments, work function difference between the second conductive pattern 159 and the drain region 12d may be smaller than work function difference between the first conductive pattern 155 and the drain region 12d.

In some example embodiments, both the first and second conductive patterns 155 and 159 may include a nitride of a first metal. However, crystal orientation of the nitride of the first metal included in the first conductive pattern 155 may be different from that of the nitride of the first metal included in the second conductive pattern 159 in FIG. 9, because of the interface pattern 157 between the first and second conductive patterns 155 and 159. The first metal may include, for example, titanium (Ti), tungsten (W), etc.

For example, if the transistor including the third gate structure 173 and the source/drain region 12 is an NMOS, work function of the source/drain region 12 including n-type impurities may be approximately 4.0 eV. In some example embodiments, if the first metal is titanium (Ti), by adjusting crystal orientation of TiN, the first conductive pattern 155 may be formed to have a relatively large work function value (for example, approximately 4.6 eV) and the second conductive pattern 159 may be formed to have a relatively small work function value (for example, approximately 4.2 eV).

Accordingly, the work function difference between the second conductive pattern 159 and the drain region 12d (approximately 0.2 eV) may be smaller than the work function difference between the first conductive pattern 155 and the drain region 12d (approximately 0.6 eV). Accordingly, the third gate structure 173 may have a high threshold voltage value and electric field in the region where the second conductive pattern 159 and the drain region 12d overlap may be suppressed, thereby reducing GIDL. Thus, electrical characteristics of the semiconductor device including the third gate structure 173 may be improved.

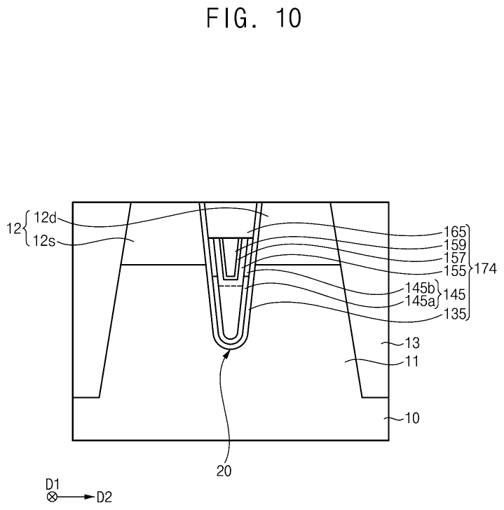

FIG. 10 is a cross-sectional view illustrating a gate structure in accordance with some example embodiments. The gate structure of FIG. 10 may be substantially the same as or similar to the gate structure of FIG. 9, and thus repeated explanations are omitted hereinafter.

Referring to FIG. 10, the first conductive pattern 155 of the fourth gate structure 174 may include a lower portion and an upper portion. The lower portion of the first conductive pattern 155 may be disposed on a lower inner wall of the first portion 145a of the second gate insulation pattern 145, and the upper portion of the first conductive pattern 155 may be, for example, conformally, disposed on an inner wall of the second portion 145b of the second gate insulation pattern 145, an upper inner wall of the first portion 145a of the second gate insulation pattern 145 and an upper surface of the lower portion. Accordingly, the first conductive pattern 155 may have, for example, a shape of a ‘V’ overall. The interface pattern 157 may be formed on an inner wall of the upper portion of the first conductive pattern 155. The second conductive pattern 159 may be formed to fill a space defined by the interface pattern 157.

For example, the interface pattern 157 may cover an outer wall and a lower surface of the second conductive pattern 159, the upper portion of the first conductive pattern 155 may cover an outer wall and a lower surface of the interface pattern 157, and the lower portion of the first conductive pattern 155 may be disposed below the upper portion of the first conductive pattern 155.

Even for a nitride of a same metal, the thinner (e.g., smaller) the thickness, the smaller the work function may be. For example, as the upper portion of the first conductive pattern 155 may have a thinner thickness than the lower portion of the first conductive pattern 155, a work function of the upper portion of the first conductive pattern 155 may be smaller than a work function of the lower portion of the first conductive pattern 155. Accordingly, a work function difference between the upper portion of the first conductive pattern 155 and the drain region 12d may be smaller than a work function difference between the lower portion of the first conductive pattern 155 and the drain region 12d. Thus, the fourth gate structure 174 may have a high threshold voltage value, and an electric field in a region where the upper portion of the first conductive pattern 155 may overlap with the drain region 12d may be suppressed, thereby reducing GIDL. Hence, electrical characteristics of the semiconductor device including the fourth gate structure 174 may be improved.

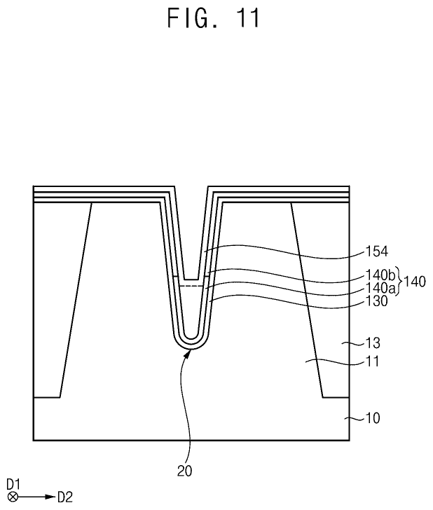

FIGS. 11 to 13 are cross-sectional views illustrating a method of manufacturing a gate structure in accordance with some example embodiments. The method of manufacturing the gate structure of FIGS. 11 to 13 may be substantially the same as or similar to the method of manufacturing the gate structure of FIGS. 1 to 5, and thus repeated explanations are omitted hereinafter.

Referring to FIG. 11, after performing processes substantially the same or similar to the processes illustrated with reference to FIGS. 2 to 4, a fifth conductive layer 154 may be formed on a surface of the second gate insulation layer 140.

In some example embodiments, the fifth conductive layer 154 may be formed to include a lower portion and an upper portion. That is, the lower portion of the fifth conductive layer 154 may be formed by forming a third conductive layer on the second gate insulation layer 140 to a height sufficient to fill the second recess 20 and performing an etch-back process on an upper portion of the third conductive layer. The upper portion of the fifth conductive layer 154 may be formed by, for example, conformally forming a fourth conductive layer on an upper surface of the third conductive layer and a surface of the second gate insulation layer 140. The third and fourth conductive layers may be merged with each other.

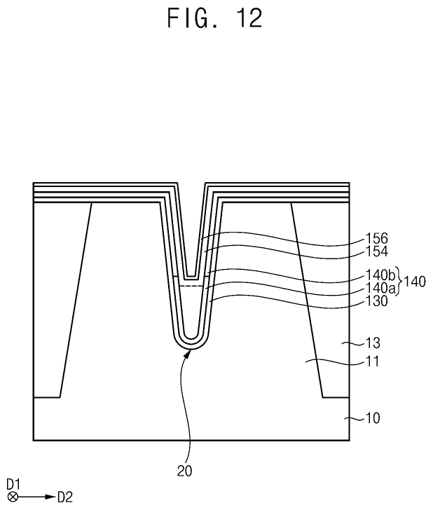

Referring to FIG. 12, the interface layer 156 may be formed, for example, conformally, on the fifth conductive layer 154.

The interface layer 156 may include, for example, silicon. The interface layer 156 may be formed by a chemical vapor deposition (CVD), an atomic layer deposition (ALD), a physical vapor deposition (PVD) process, etc.

Referring to FIG. 13, a sixth conductive layer may be formed on the interface layer 156 to a height sufficient to fill the second recess 20, and the sixth conductive layer, the interface layer 156, the fifth conductive layer 154, the second gate insulation layer 140 and the first gate insulation layer 130 may be planarized until the upper surfaces of the first active pattern 11 and the first isolation pattern 13 are exposed to form a second conductive pattern 159, an interface pattern 157, a first conductive pattern 155, a second gate insulation pattern 145 and a first gate insulation pattern 135.

Thereafter, manufacturing of the fourth gate structure 174 may be completed by performing processes substantially the same as or similar to the processes illustrated with reference to FIG. 1.

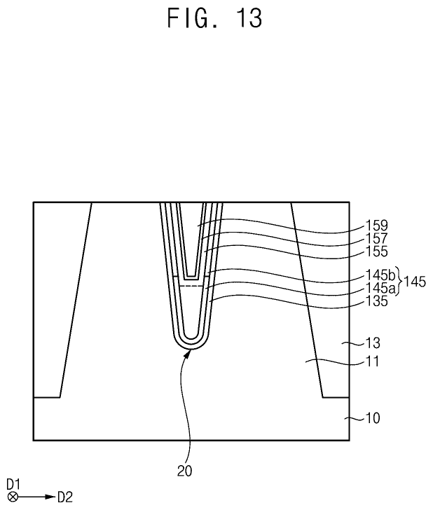

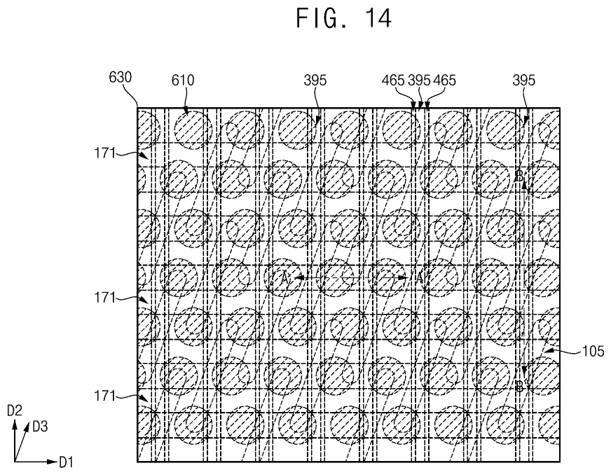

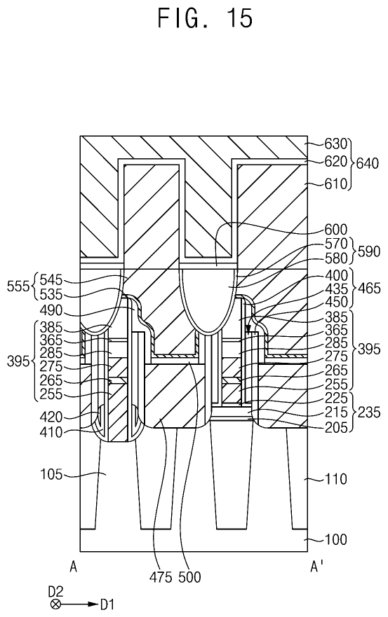

FIG. 14 is a plan view illustrating a semiconductor device in accordance with some example embodiments, FIG. 15 is a cross-sectional view taken along line A-A′ of FIG. 14, and FIG. 16 is a cross-sectional view taken along line B-B′ of FIG. 14.

This semiconductor device may be an application of the first gate structure illustrated with reference to FIG. 1 to a DRAM device, and thus repeated explanations on the first gate structure 171 are omitted hereinafter. However, in some example embodiments the semiconductor device may include one of the second to fourth gate structures 172, 173 and 174 shown in FIGS. 6, 9 and 10 instead of the first gate structure 171.

Referring to FIGS. 14 to 16, the semiconductor device may include a second active pattern 105, a first gate structure 171, a bit line structure 395, a contact plug structure, and a capacitor 640 on the second substrate 100.

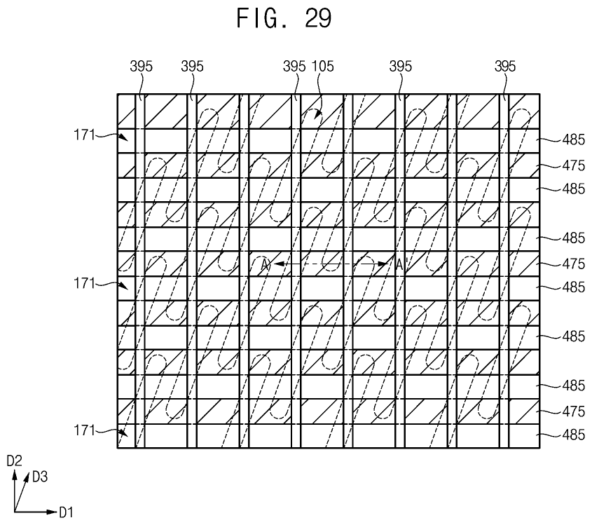

The semiconductor device may further include a second isolation pattern 110, a spacer structure 465, a fourth spacer 490, a second capping pattern 485 (e.g., see FIG. 29), first and second insulation pattern structures 235 and 590, fourth and fifth insulation patterns 410 and 420, and a metal silicide pattern 500.

The second active pattern 105 may extend in the third direction D3, and a plurality of second active patterns 105 may be spaced apart from each other in the first and second directions D1 and D2. A sidewall of the second active pattern 105 may be covered by the second isolation pattern 110. The second active pattern 105 may include the same or substantially the same material as the second substrate 100, and the second isolation pattern 110 may include an oxide, e.g., silicon oxide.

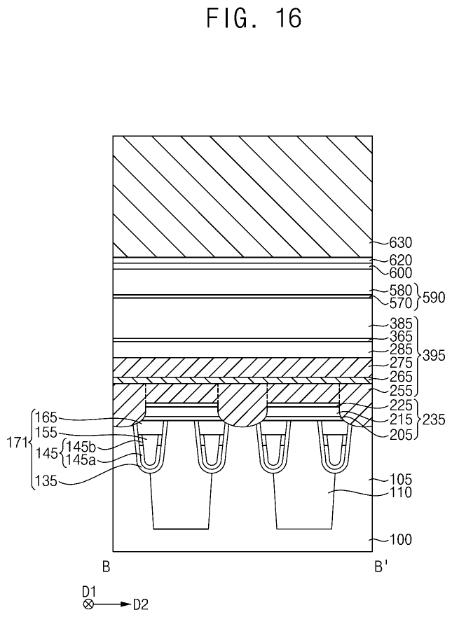

Referring to FIGS. 14 to 16 together with FIG. 17, the first gate structure 171 may be formed in a fifth recess extending in the first direction D1 through upper portions of the second active pattern 105 and the second isolation pattern 110.

In some example embodiments, the first gate structure 171 may extend in the first direction D1, and a plurality of first gate structures 171 may be spaced apart from each other in the second direction D2.

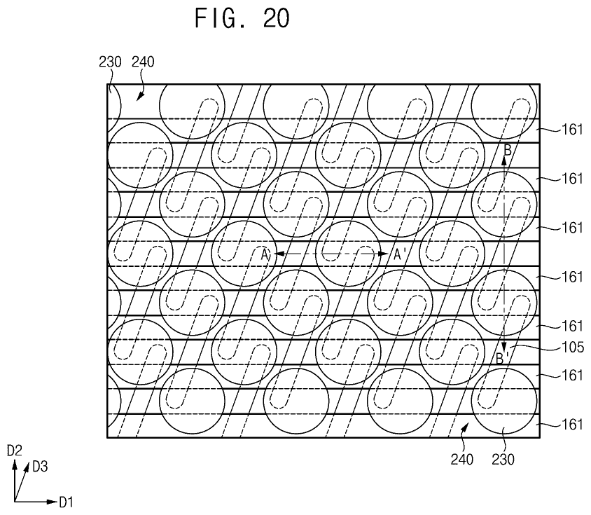

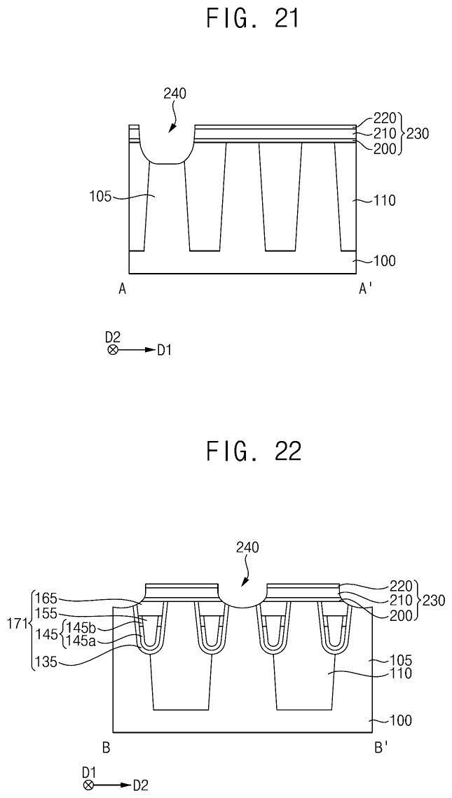

Referring to FIGS. 14 to 16 together with FIGS. 20 to 22, a first opening 240 extending through an insulation layer structure 230 and exposing upper surfaces of the second active pattern 105, the second isolation pattern 110 and the gate mask 165 of the first gate D3 of the second active pattern 105 may be exposed by the first opening 240.

In some example embodiments, an area of a bottom of the first opening 240 may be greater than an area of the upper surface of the second active pattern 105. Thus, the first opening 240 may also expose an upper surface of a portion of the second isolation pattern 110 adjacent to the second active pattern 105. The first opening 240 may extend through upper portions of the second active pattern 105 and the portion of the second isolation pattern 110 adjacent thereto, and thus the bottom of the first opening 240 may be lower than an upper surface of each of opposite edge portions in the third direction D3 of the second active pattern 105.

The bit line structure 395 may include a third conductive pattern 255, a first barrier pattern 265, a fourth conductive pattern 275, a first mask 285, a first etch stop pattern 365 and a first capping pattern 385 sequentially stacked in the vertical direction on the first opening 240 or the first insulation pattern structure 235. The third conductive pattern 255, the first barrier pattern 265 and the fourth conductive pattern 275 may collectively form a conductive structure, and the first mask 285, the first etch stop pattern 365 and the first capping pattern 385 may collectively form an insulation structure.

The third conductive pattern 255 may include, e.g., doped polysilicon, the first barrier pattern 265 may include a metal nitride, e.g., titanium nitride, or a metal silicon nitride, e.g., titanium silicon nitride, the fourth conductive pattern 275 may include a metal, e.g., tungsten, and each of the first mask 285, the first etch stop pattern 365 and the first capping pattern 385 may include an insulating nitride, e.g., silicon nitride.

In some example embodiments, the bit line structure 395 may extend in the second direction D2 on the second substrate 100, and a plurality of bit line structures 395 may be spaced apart from each other in the first direction D1.

The fourth and fifth insulation patterns 410 and 420 may be formed in the first opening 240, and may contact a lower sidewall of the bit line structure 395. The fourth insulation pattern 410 may include an oxide, e.g., silicon oxide, and the fifth insulation pattern 420 may include an insulating nitride, e.g., silicon nitride.

The first insulation pattern structure 235 may be formed on the second active pattern 105 and the second isolation pattern 110 under the bit line structure 395, and may include first, second and third insulation patterns 205, 215 and 225 sequentially stacked in the vertical direction. The first and third insulation patterns 205 and 225 may include an oxide, e.g., silicon oxide, and the second insulation pattern 215 may include an insulating nitride, e.g., silicon nitride.

The contact plug structure may include a lower contact plug 475, a metal silicide pattern 500 and an upper contact plug 555 sequentially stacked in the vertical direction on the second active pattern 105 and the second isolation pattern 110.

The lower contact plug 475 may contact the upper surface of each of opposite edge portions in the third direction D3 of the second active pattern 105. In some example embodiments, a plurality of lower contact plugs 475 may be spaced apart from each other in the second direction D2, and a second capping pattern 485 may be formed between neighboring ones of the lower contact plugs 475 in the second direction D2. The second capping pattern 485 may include an insulating nitride, e.g., silicon nitride.

The lower contact plug 475 may include, e.g., doped polysilicon, the metal silicide pattern 500 may include, e.g., titanium silicide, cobalt silicide, nickel silicide, etc.

The upper contact plug 555 may include a second metal pattern 545 and a second barrier pattern 535 covering a lower surface of the second metal pattern 545. The second metal pattern 545 may include a metal, e.g., tungsten, and the second barrier pattern 535 may include a metal nitride, e.g., titanium nitride.

In some example embodiments, a plurality of upper contact plugs 555 may be spaced apart from each other in the first and second directions D1 and D2, and may be arranged in a honeycomb pattern or a lattice pattern in a plan view. Each of the upper contact plugs 555 may have a shape of, e.g., a circle, an ellipse, or a polygon in a plan view.

The spacer structure 465 may include a first spacer 400 covering sidewalls of the bit line structure 395 and the third insulation pattern 225, an air spacer 435 on a lower outer sidewall of the first spacer 400, and a third spacer 450 on an outer sidewall of the air spacer 435, a sidewall of the first insulation pattern structure 235, and upper surfaces of the fourth and fifth insulation patterns 410 and 420.

Each of the first and third spacers 400 and 450 may include an insulating nitride, e.g., silicon nitride, and the air spacer 435 may include air.

The fourth spacer 490 may be formed on an outer sidewall of a portion of the first spacer 400 on an upper sidewall of the bit line structure 395, and may cover an upper end of the air spacer 435 and an upper surface of the third spacer 450. The fourth spacer 490 may include an insulating nitride, e.g., silicon nitride.

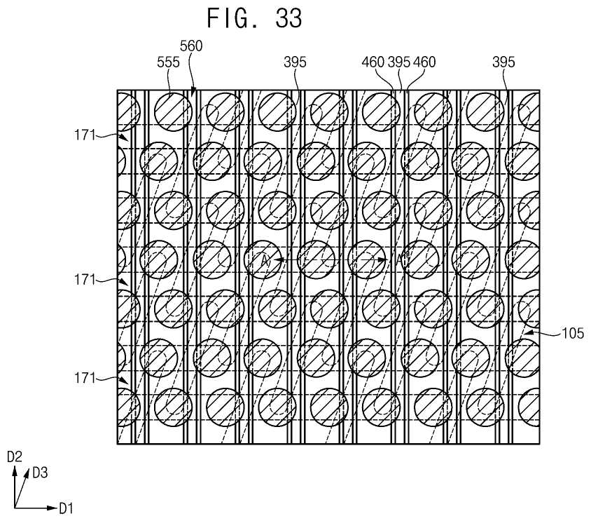

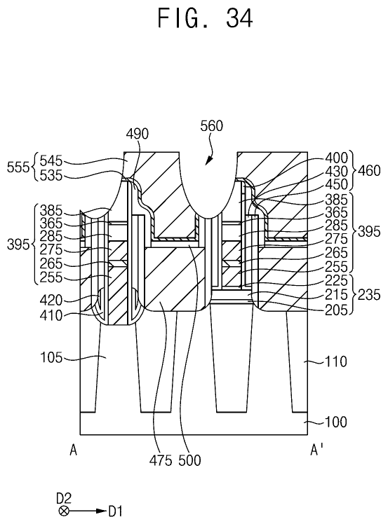

Referring to FIGS. 14 to 16 together with FIGS. 33 and 34, the second insulation pattern structure 590 may include a sixth insulation pattern 570 on an inner wall of a sixth opening 560, which may extend through the upper contact plug 555, a portion of the insulation structure of the bit line structure 395 and portions of the first, third and fourth spacers 400, 450 and 490 and surround the upper contact plug 555 in a plan view, and an seventh insulation pattern 580 on the sixth insulation pattern 570 and fill a remaining portion of the sixth opening 560. The upper end of the air spacer 435 may be closed by the sixth insulation pattern 570.

The sixth and seventh insulation patterns 570 and 580 may include an insulating nitride, e.g., silicon nitride.

The second etch stop pattern 600 may be formed on the sixth and seventh insulation patterns 570 and 580, the upper contact plug 555 and the second capping pattern 485. The second etch stop pattern 600 may include, an insulating nitride, e.g., silicon boronitride, silicon nitride, etc.

The capacitor 640 may include a lower electrode 610, a dielectric layer 620 and an upper electrode 630 that are sequentially stacked, and the lower electrode 610 may extend through the second etch stop pattern 600 to contact an upper surface of the upper contact plug 555. Each of the lower electrode 610 and the upper electrode 630 may include, e.g., metal, metal nitride, metal silicide, and the dielectric layer 620 may include, e.g., metal oxide.

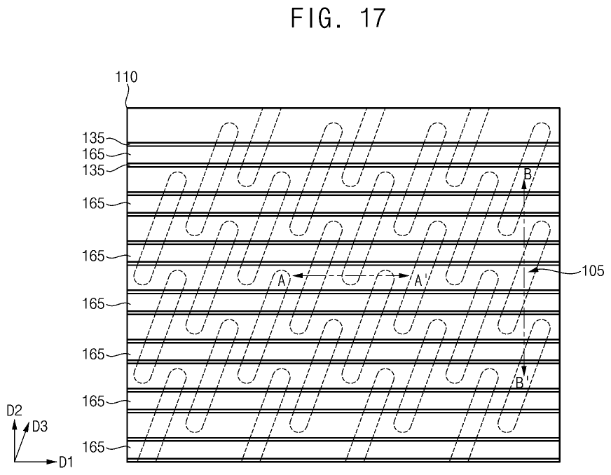

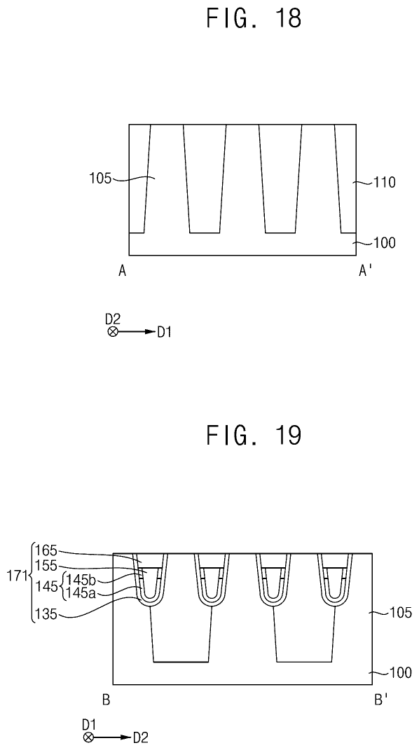

FIGS. 17 to 35 are plan views and cross-sectional views illustrating a method of manufacturing a semiconductor device according to some example embodiments. For example, FIGS. 17, 20, 25, 29 and 33 are the plan views, FIGS. 18, 21, 23, 26-28, 30-32 and 34-35 are cross-sectional views taken along lines A-A′, respectively, of corresponding plan views, and FIGS. 19, 22 and 24 are cross-sectional views taken along lines B-B′, respectively, of corresponding plan views.

The method of manufacturing the semiconductor device is an application of the method of forming the first gate structure 171 described with reference to FIGS. 1 to 5 to a method of manufacturing a DRAM device, and repeated explanations of the method of forming the first gate structure 171 are omitted hereinafter.

Referring to FIGS. 17 to 19, an upper portion of a second substrate 100 may be removed to form a fourth recess, and a second isolation pattern 110 may be formed in the fourth recess.

As the second isolation pattern 110 is formed on the second substrate 100, a second active pattern 105 of which a sidewall is covered by the second isolation pattern 110 may be defined.

The second active pattern 105 and the second isolation pattern 110 on the second substrate 100 may be partially etched to form a fifth recess extending in the first direction D1, and a first gate structure 171 may be formed in the fifth recess. In some example embodiments, the first gate structure 171 may extend in the first direction D1, and a plurality of gate structures may be spaced apart from each other in the second direction D2.

Referring to FIGS. 20 to 22, an insulating layer structure 230 may be formed on the second active pattern 105, the second isolation pattern 110, and the first gate structure 171. The insulating layer structure 230 may include first to third insulating layers 200, 210, and 220 sequentially stacked.

The insulating layer structure 230 may be patterned, and the second active pattern 105, the second isolation pattern 110, and the gate mask 165 included in the first gate structure 171 may be partially etched using the patterned insulating layer structure 230 as an etching mask to form a first opening 240. In some example embodiments, the insulating layer structure 230 may have a circular shape or an elliptical shape in a plain view, and a plurality of insulating layer structures 230 may be spaced apart from each other in the first and second direction D1 and D2. Each of the insulating layer structures 230 may overlap end portions of ones of the second active patterns 105 neighboring in the third direction D3, which may face each other, in a vertical direction substantially orthogonal to the upper surface of the second substrate 100.

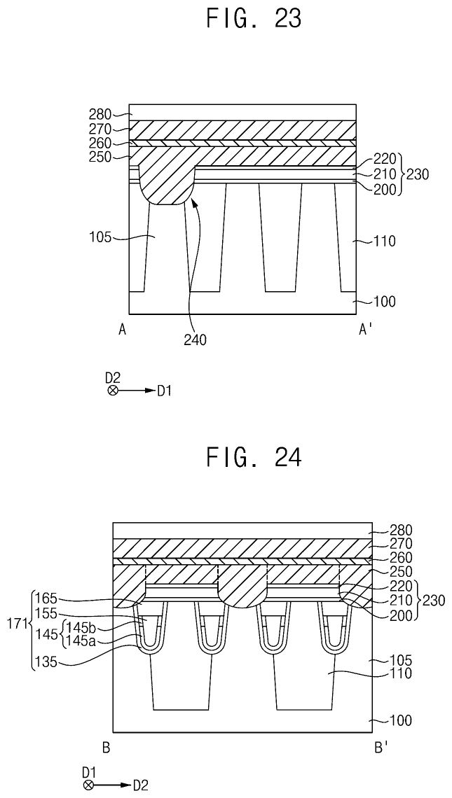

Referring to FIGS. 23 and 24, a seventh conductive layer 250, a first barrier layer 260, an eighth conductive layer 270 and a first mask layer 280 may be sequentially stacked on the insulating layer structure 230, and the second active pattern 105, the second isolation pattern 110 and the first gate structure 171 exposed by the first opening 240. The seventh conductive layer 250 may fill the first opening 240.

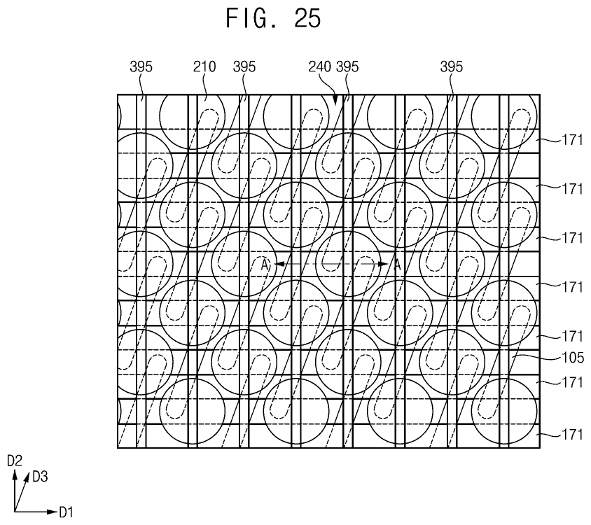

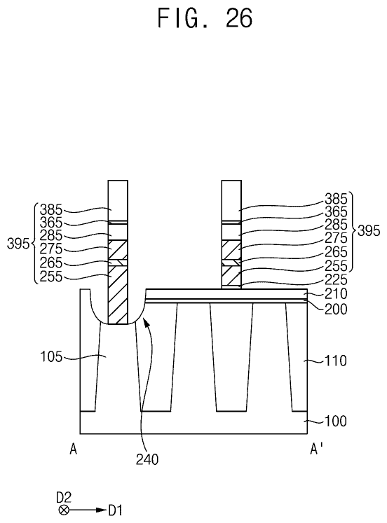

Referring to FIGS. 25 and 26, a first etch stop layer and a first capping layer may be sequentially formed on the conductive structure layer, the first capping layer may be etched to form a first capping pattern 385, and the first etch stop layer, the first mask layer 280, the eighth conductive layer 270, the first barrier layer 260 and the seventh conductive layer 250 may be sequentially etched using the first capping pattern 385 as an etch mask.

In some example embodiments, the first capping pattern 385 may extend in the second direction D2, and a plurality of first capping patterns 385 may be spaced apart from each other in the first direction D1.

By the etching process, a third conductive pattern 255, a first barrier pattern 265, a fourth conductive pattern 275, a first mask 285, a first etch stop pattern 365 and the first capping pattern 385 may be formed on the first opening 240, and a third insulation pattern 225, the third conductive pattern 255, the first barrier pattern 265, the fourth conductive pattern 275, the first mask 285, the first etch stop pattern 365 and the first capping pattern 385 may be sequentially stacked on the second insulating layer 210 of the insulating layer structure 230 at an outside of the first opening 240.

Hereinafter, the third conductive pattern 255, the first barrier pattern 265, the fourth conductive pattern 275, the first mask 285, the first etch stop pattern 365 and the first capping pattern 385 sequentially stacked may be referred to as a bit line structure 395. The third conductive pattern 255, the first barrier pattern 265 and the fourth conductive pattern 275 may form a conductive structure, and the first mask 285, the first etch stop pattern 365 and the first capping pattern 385 may form an insulating structure. In some example embodiments, the bit line structure 395 may extend in the second direction D2, and a plurality of bit line structures 395 may be spaced apart from each other in the first direction D1.

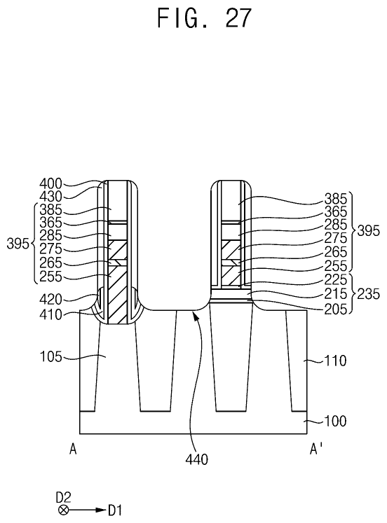

Referring to FIG. 27, a first spacer layer may be formed on the second substrate 100 on which the bit line structure 395 is formed, and fourth and fifth insulating layers may be sequentially formed on the first spacer layer.

The first spacer layer may also cover a sidewall of the third insulation pattern 225 under the bit line structure 395 on the second insulating layer 210, and the fifth insulating layer may fill a remaining portion of the first opening 240.

The fourth and fifth insulating layers may be etched by an etching process. In some example embodiments, the etching process may be a wet etching process using, for example, phosphoric acid (H₂PO₃), SC₁, and hydrofluoric acid (HF) as an etchant, and portions of the fourth and fifth insulating layers except for portions thereof in the first opening 240 may be removed. Accordingly, most portion of a surface of the first spacer layer, that is, all portions of the surface of the first spacer layer except for a portion of the surface thereof in the first opening 240 may be exposed, and the fourth and fifth insulating layers remaining in the first opening 240 may form fourth and fifth insulation patterns 410 and 420, respectively.

A second spacer layer may be formed on the exposed surface of the first spacer layer and the fourth and fifth insulation patterns 410 and 420 in the first opening 240. The second spacer layer may be anisotropically etched to form a second spacer 430 covering a sidewall of the bit line structure 395 on the surface of the first spacer layer and on the fourth and fifth insulation patterns 410 and 420.

A dry etching process may be performed using the first capping pattern 385 and the second spacer 430 as an etch mask to form a second opening 440 exposing an upper surface of the second active pattern 105, and upper surfaces of the second isolation pattern 110 and the gate mask 150 may also be exposed by the second opening 440.

By the dry etching process, portions of the first spacer layer on upper surfaces of the first capping pattern 385 and the second insulating layer 210 may be removed, and thus a first spacer 400 may be formed on the sidewall of the bit line structure 395. By the dry etching process, the first and second insulating layers 200 and 210 may be partially removed to remain as first and second insulation patterns 205 and 215, respectively, under the bit line structure 395. The first to third insulation patterns 205, 215 and 225 sequentially stacked under the bit line structure 395 may form a first insulation pattern structure.

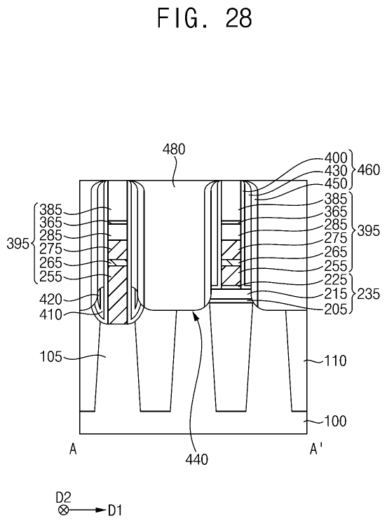

Referring to FIG. 28, a third spacer layer may be formed on an upper surface of the first capping pattern 385, an outer sidewall of the second spacer 430, portions of the upper surfaces of the fourth and fifth insulation patterns 410 and 420, and upper surfaces of the second active pattern 105, the second isolation pattern 110 and the gate mask 150 exposed by the second opening 440. The third spacer layer may be anisotropically etched to form a third spacer 450 covering the sidewall of the bit line structure 395.

The first to third spacers 400, 430 and 450 sequentially stacked on the sidewall of the bit line structure 395 in the horizontal direction may be referred to as a preliminary spacer structure 460.

A sacrificial layer may be formed to fill the second opening 440 on the second substrate 100 to a sufficient height, and an upper portion of the sacrificial layer may be planarized until the upper surface of the first capping pattern 385 is exposed to form a sacrificial pattern 480 in the second opening 440.

In some example embodiments, the sacrificial pattern 480 may extend in the second direction D2, and a plurality of sacrificial patterns 480 may be spaced apart from each other in the first direction D1 by the bit line structures 395. The sacrificial pattern 480 may include, for example, an oxide such as silicon oxide.

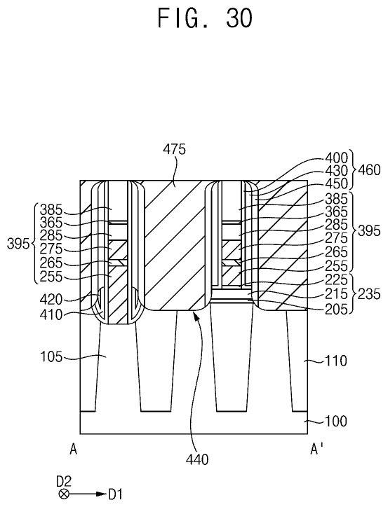

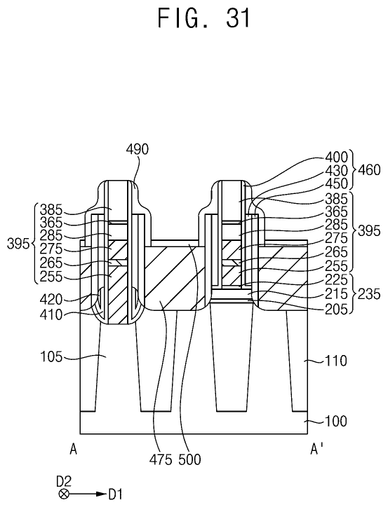

Referring to FIGS. 29 and 30, a second mask including a plurality of third openings, each of which may extend in the first direction D1, spaced apart from each other in the second direction D2 may be formed on the first capping pattern 385, the sacrificial pattern 480 and the preliminary spacer structure 460, and may be etched using the second mask as an etching mask.

In some example embodiments, each of the third openings may overlap a region between the first gate structures 171 in the vertical direction. By the etching process, a fourth opening exposing upper surfaces of the second active pattern 105 and the second isolation pattern 110 may be formed between the bit line structures 395 on the second substrate 100.

The second mask may be removed, a lower contact plug layer may be formed to fill the fourth opening to a sufficient height, and an upper portion of the lower contact plug layer may be planarized until the upper surface of the first capping pattern 385 and upper surfaces of the sacrificial pattern 480 and the preliminary spacer structure 460 are exposed. Thus, the lower contact plug layer may be transformed into a plurality of lower contact plugs 475 spaced apart from each other in the second direction D2 between the bit line structures 395. The sacrificial pattern 480 extending in the second direction D2 between the bit line structures 395 may be divided into a plurality of parts in the second direction D2 by the lower contact plugs 475.

The sacrificial pattern 480 may be removed to form a fifth opening, and a second capping pattern 485 may be formed to fill the fifth opening. In some example embodiments, the second capping pattern 485 may overlap the first gate structure 171 in the vertical direction.

Referring to FIG. 31, an upper portion of the lower contact plug 475 may be removed to expose an upper portion of the preliminary spacer structure 460 on the sidewall of the bit line structure 395, and upper portions of the second and third spacers 430 and 450 of the exposed preliminary spacer structure 460 may be removed.

An upper portion of the lower contact plug 475 may be additionally removed. Thus, an upper surface of the lower contact plug 475 may be lower than upper surfaces of the second and third spacers 430 and 450.

A fourth spacer layer may be formed on the bit line structure 395, the preliminary spacer structure 460, the second capping pattern 485 and the lower contact plug 475, and may be anisotropically etched to form a fourth spacer 490 covering an upper portion of the preliminary spacer structure 460 on the sidewall of the bit line structure 395, and the upper surface of the lower contact plug 475 may be exposed by the etching process.

A metal silicide pattern 500 may be formed on the exposed upper surface of the lower contact plug 475. In some example embodiments, the metal silicide pattern 500 may be formed by forming a first metal layer on the first and second capping patterns 385 and 485, the fourth spacer 490 and the lower contact plug 475, performing a heat treatment thereon, and removing an unreacted portion of the first metal layer.

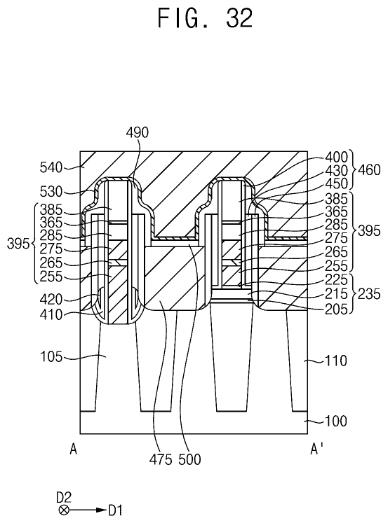

Referring to FIG. 32, a second barrier layer 530 may be formed on the first and second capping patterns 385 and 485, the fourth spacer 490, the metal silicide pattern 500 and the lower contact plug 475, and a second metal layer 540 may be formed on the second barrier layer 530 to fill a space between the bit line structures 395.

A planarization process may be performed on an upper portion of the second metal layer 540. The planarization process may include, for example, a chemical mechanical polishing (CMP) process and/or an etch-back process.

Referring to FIGS. 33 and 34, the second metal layer 540 and the second barrier layer 530 may be patterned to form an upper contact plug 555. In some example embodiments, a plurality of upper contact plugs 555 may be formed, and a sixth opening 560 may be formed between the upper contact plugs 555.

The sixth opening 560 may be formed by partially removing the first and second capping patterns 385 and 485, the preliminary spacer structure 460 and the fourth spacer 490 as well as the second metal layer 540 and the second barrier layer 530.

The upper contact plug 555 may include a second metal pattern 545 and a second barrier pattern 535 covering a lower surface of the second metal pattern 545. In some example embodiments, the upper contact plug 555 may have a shape of a circle, an ellipse, or a rounded polygon in a plan view, and the upper contact plugs 555 may be arranged, for example, in a honeycomb pattern in the first and second direction D1 and D2, in a plan view.

The lower contact plug 475, the metal silicide pattern 500 and the upper contact plug 555 sequentially stacked on the second substrate 100 may collectively form a contact plug structure.

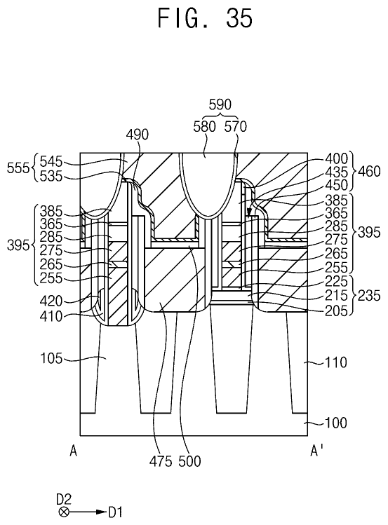

Referring to FIG. 35, the second spacer 430 included in the preliminary spacer structure 460 exposed by the sixth opening 560 may be removed to form an air gap, a sixth insulation pattern 570 may be formed on a bottom and a sidewall of the sixth opening 560, and a seventh insulation pattern 580 may be formed to fill a remaining portion of the sixth opening 560.

Each of the sixth and seventh insulation patterns 570 and 580 may form a second insulation pattern structure 590.

A top end of the air gap may be covered by the sixth insulation pattern 570, and thus an air spacer 435 may be formed. The first spacer 400, the air spacer 435 and the third spacer 450 may form a spacer structure 465.

Referring to FIGS. 14 to 16 again, a capacitor 640 may be formed to contact an upper surface of the upper contact plug 555.

That is, a second etch stop pattern 600 and a mold layer may be sequentially formed on the second insulation pattern structure 590 and the upper contact plug 555, and a seventh opening may be formed to expose an upper surface of the upper contact plug 555.

The seventh opening exposing the upper contact plug 555 may be arranged in a honeycomb pattern or a lattice pattern in a plan view, corresponding to the upper contact plug 555.

A lower electrode 610, that may have a shape of, for example, a pillar, may be formed within the seventh opening, the mold layer may be removed, and a dielectric layer 620 and an upper electrode 630 may be formed on the lower electrode 610 and the second etch stop pattern 600. The lower electrode 610, the dielectric layer and the upper electrode 630 sequentially stacked may together form the capacitor 640.

Alternatively, the lower electrode 610 may be formed to have a shape of a cylinder within the seventh opening.

The manufacturing of the semiconductor device may be completed by forming upper wirings on the capacitor 640.

While the present inventive concepts have been shown and described with reference to some example embodiments thereof, it will be understood by those of ordinary skill in the art that various changes in form and details may be made thereto without departing from the spirit and scope of the present inventive concepts as set forth by the following claims.

What is claimed is:

1. A semiconductor device comprising:
an active pattern on a substrate, the active pattern defining a recess extending through an upper portion of the active pattern;
a gate structure including
a first gate insulation pattern on an inner wall of the recess,
a second gate insulation pattern having
a first portion at a lower inner wall of the first gate insulation pattern, the first portion containing a metal oxide, and
a second portion at an upper inner wall of the first gate insulation pattern, the second portion contacting the first portion, and the second portion containing the metal oxide doped with at least one of n-type impurities, p-type impurities or germanium, and
a conductive structure on the second gate insulation pattern; and
a source/drain region at an upper portion of the active pattern adjacent to the gate structure.

2. The semiconductor device of claim 1, wherein the metal oxide includes at least one of lanthanum oxide, hafnium oxide, tantalum oxide, or zirconium oxide.

3. The semiconductor device of claim 1, wherein the first gate insulation pattern includes silicon oxide.

4. The semiconductor device of claim 1, wherein the second portion of the second gate insulation pattern at least partially overlaps the source/drain region in a horizontal direction parallel to an upper surface of the substrate.

5. The semiconductor device of claim 4, wherein a lower surface of the second portion of the second gate insulation pattern is lower than a lower surface of the source/drain region.

6. The semiconductor device of claim 1, wherein the conductive structure includes a first conductive pattern and a second conductive pattern sequentially stacked on the second gate insulation pattern.

7. The semiconductor device of claim 6, wherein an upper portion of the first conductive pattern further contains at least one of n-type impurities, p-type impurities or germanium.

8. The semiconductor device of claim 7, wherein a crystal orientation of the first conductive pattern is a same crystal orientation as a crystal orientation of the second conductive pattern.

9. The semiconductor device of claim 6, wherein the first conductive pattern includes a metal nitride and the second conductive pattern includes a metal.

10. A semiconductor device comprising:
an active pattern on a substrate;
a gate structure including
a conductive structure extending through an upper portion of the active pattern, the conductive structure having a first conductive pattern, an interface pattern and a second conductive pattern sequentially stacked, wherein the interface pattern contains silicon, and
a first gate insulation pattern having
a first portion covering a lower outer wall of the conductive structure, the first portion containing a metal oxide, and
a second portion covering an upper outer wall of the conductive structure, the second portion containing the metal oxide doped with impurities; and
a source/drain region at an upper portion of the active pattern adjacent to the gate structure.

11. The semiconductor device of claim 10, wherein the metal oxide includes at least one of lanthanum oxide, hafnium oxide, tantalum oxide, or zirconium oxide.

12. The semiconductor device of claim 10, wherein the impurities include at least one of n-type impurities, p-type impurities or germanium.

13. The semiconductor device of claim 10, further comprising a second gate insulation pattern covering an outer wall of the first gate insulation pattern, wherein the second gate insulation pattern contains silicon oxide.

14. The semiconductor device of claim 10, wherein
the first and second conductive patterns both include a nitride of a first metal, and
a crystal orientation of the first conductive pattern and a crystal orientation of the second conductive pattern are different from each other, and a work function difference between the second conductive pattern and the source/drain region is smaller than a work function difference between the first conductive pattern and the source/drain region.

15. The semiconductor device of claim 10, wherein
the interface pattern covers an outer sidewall and a lower surface of the second conductive pattern, the first conductive pattern includes an upper portion and a lower portion below the upper portion, and the upper portion covers an outer sidewall and a lower surface of the interface pattern, and
a work function difference between the upper portion of the first conductive pattern and the source/drain region is smaller than a work function difference between the lower portion of the first conductive pattern and the source/drain region.

16. A semiconductor device comprising:
an active pattern on a substrate, the active pattern defining a recess extending through an upper portion of the active pattern;
an isolation pattern covering a sidewall of the active pattern;
a gate structure extending in a first direction parallel to an upper surface of the substrate through the upper portion of the active pattern and an upper portion of the isolation pattern;
a source/drain region at the upper portion of the active pattern adjacent to the gate structure;
a bit line structure contacting a central portion of an upper surface of the active pattern, the bit line structure extending in a second direction parallel to the upper surface of the substrate and perpendicular to the first direction;
a contact plug structure contacting each opposite end portions of the upper surface of the active pattern; and
a capacitor on the contact plug structure,
wherein the gate structure includes
a first gate insulation pattern on an inner wall of the recess,
a second gate insulation pattern having
a first portion at a lower inner wall of the first gate insulation pattern, the first portion containing a metal oxide, and
a second portion at an upper inner wall of the first gate insulation pattern, the second portion contacting the first portion, and the second portion containing the metal oxide doped with impurities, and
a conductive structure on the second gate insulation pattern, the conductive structure having a first conductive pattern and a second conductive pattern sequentially stacked on the second gate insulation pattern.

17. The semiconductor device of claim 16, wherein the first conductive pattern includes a same material as the second conductive pattern.

18. The semiconductor device of claim 16, wherein an upper portion of the first conductive pattern further includes the impurities.

19. The semiconductor device of claim 16, further comprising an interface pattern between the first and second conductive patterns, the interface pattern containing silicon, and
wherein the first and second conductive patterns include a nitride of a first metal, a crystal orientation of the first conductive pattern and a crystal orientation of the second conductive pattern are different from each other, and a work function difference between the second conductive pattern and the source/drain region is smaller than a work function difference between the first conductive pattern and the source/drain region.

20. The semiconductor device of claim 16, further comprising an interface pattern between the first and second conductive patterns, the interface pattern containing silicon, and
wherein the interface pattern covers an outer sidewall and a lower surface of the second conductive pattern, the first conductive pattern includes an upper portion and a lower portion below the upper portion, and the upper portion covers an outer sidewall and a lower surface of the interface pattern, and
wherein a work function difference between the upper portion of the first conductive pattern and the source/drain region is smaller than a work function difference between the lower portion of the first conductive pattern and the source/drain region.
